(19) United States
(12) Patent Application Publication
(10) Pub. No.: US 2016/0380604 A1
(43) Pub. Date: Dec. 29, 2016

(54) TRANSFORMER BASED DUPLEXER

(71) Applicant: INTEL IP CORPORATION, Santa Clara, CA (US)

(72) Inventors: Gregory Chance, Oberhaching (DE); Nebil Tanzi, Hoffman Estates, IL (US)

(21) Appl. No.: 14/752,811

(22) Filed: Jun. 26, 2015

(51) Int. Cl. H03H 2/00; H01F 38/14; H03H 11/04

(52) U.S. Cl. CPC H03H 2/005; H03H 11/04; H01F 38/14; H01F 2038/143

(57) ABSTRACT

A tunable transformer based duplexer (TTBD) comprising a first antenna port and a second antenna port. The TTBD further comprises a first winding coupled between a transmitting port and the first antenna port, wherein the first antenna port is configured to receive a first signal; a second winding coupled between the transmitting port and the second antenna port, wherein the second antenna port is configured to receive a second signal. Further, the TTBD comprises a receiving amplifier comprising at least one input and at least one output. The TTBD also comprises a third winding comprising a first terminal and a second terminal. The third winding comprises a first inductance and is coupled to the at least one output of the amplifier circuit. A first coupling is formed between the first winding and the third winding and a second coupling is formed between the second winding and the third winding. The TTBD further comprises a tunable capacitance coupled between the first terminal and the second terminal of the third winding. The tunable capacitance and the first inductance together form a band-pass filter.

### FIELD

The present disclosure relates to a hybrid transformer based duplexer system with two antenna ports.

### BACKGROUND

In Radio Frequency (RF) communication systems, acoustic filters like Surface Acoustic Wave (SAW) filters, Bulk Acoustic Wave (BAW) filters and Film Bulk Acoustic Resonator (FBAR) filters are used to provide isolation between the transmitted signal and the receiver. These acoustic filters represent a significant portion of the total RF solution Bill of Materials (BOM) cost for cellular communication systems. The replacement of these multiple acoustic filters with one tunable filter would significantly reduce the RF cost involved in the manufacture of a RF communication system.

A center tapped hybrid transformer can be used as a duplexer to provide isolation between the transmitted signal and the receiver. However, the center tapped hybrid transformer causes high transmit insertion loss and receive insertion loss. It is advantageous to minimize these losses in the duplexer to make it more efficient.

### BRIEF DESCRIPTION OF THE DRAWINGS

FIG. 1A illustrates a center tapped hybrid transformer based duplexer system showing the transmit signal flow.

FIG. 1B illustrates a center tapped hybrid transformer based duplexer system showing the receive signal flow.

FIG. 2A illustrates a Hybrid Transformer based Duplexer (HTBD) system showing the transmit signal flow.

FIG. 2B illustrates a HTBD system showing a receive signal flow.

FIG. 3A illustrates a HTBD system with a feedback circuit.

FIG. 3B illustrates an embodiment of the HTBD system comprising a single ended low noise amplifier.

FIG. 4 illustrates a Tunable Transformer based Duplexer system.

FIG. 5 illustrates a method to optimize the transmit insertion loss and the receive insertion loss.

### DETAILED DESCRIPTION

In the present disclosure, a Hybrid Transformer based Duplexer (HTBD) is disclosed. The HTBD comprises a first winding coupled between a power amplifier port and a first antenna port, a second winding coupled between the power amplifier port and a second antenna port. The HTBD further comprises an amplifier circuit comprising at least one input and at least one output. The HTBD further comprises a third winding coupled to the at least one input of the amplifier circuit. A first coupling is formed between the first winding and the third winding and a second coupling is formed between the second winding and the third winding. Further, the HTBD comprises a programmable phase shifter circuit coupled between the second winding and the second antenna port, wherein the programmable phase shifter is configured to shift the phase of the second signal. The HTBD further comprises a feedback circuit coupled to at least one output of the amplifier circuit. The feedback circuit is configured to generate feedback information based on the first signal and the second signal. In one embodiment, the amplifier circuit comprises a differential amplifier comprising a first input, a second input, a first output and a second output. In another embodiment, the amplifier circuit comprises a single ended amplifier comprising a first input and a first output. These embodiments are appreciated in detail in this disclosure.

In another embodiment of the disclosure, a tunable transformer based duplexer (TTBD) system is disclosed. The TTBD comprises a first winding coupled between a power amplifier port and a first antenna port and a second winding coupled between the power amplifier port and a second antenna port. The TTBD further comprises an amplifier circuit comprising at least one input and at least one output. Further, the TTBD comprises a third winding comprising a first terminal and a second terminal. A first coupling is formed between the first winding and the third winding. A second coupling is formed between the second winding and the third winding. The TTBD further comprises a tunable capacitance between the first terminal and the second terminal of the third winding. The TTBD also comprises a programmable phase shifter circuit coupled between the second winding and the second antenna port, wherein the programmable phase shifter circuit is configured to shift the phase of the second signal. In one embodiment, the amplifier circuit comprises a differential amplifier comprising a first input, a second input, a first output and a second output. In another embodiment, the amplifier circuit comprises a single ended amplifier comprising a first input and a first output. These embodiments are appreciated in detail in this disclosure.

The present disclosure will now be described with reference to the attached figures, wherein like reference numerals are used to refer to like elements throughout, and wherein the illustrated structures and devices are not necessarily drawn to scale. As utilized herein, terms “component,” “system,” “interface,” “decoder” and the like are intended to refer to a circuit related entity, hardware, software (e.g., in execution), or firmware or a combination thereof. As another example, a component can be an apparatus with specific functionality provided by mechanical parts operated by electric or electronic circuitry, in which the electric or electronic circuitry can be operated by a software application or a firmware application executed by one or more processors. The one or more processors can be internal or external to the apparatus and can execute at least a part of the software or firmware application. As yet another example, a component can be an apparatus that provides specific functionality through electronic components without mechanical parts; the electronic components can include one or more processors therein to execute software and/or firmware that confer(s), at least in part, the functionality of the electronic components.

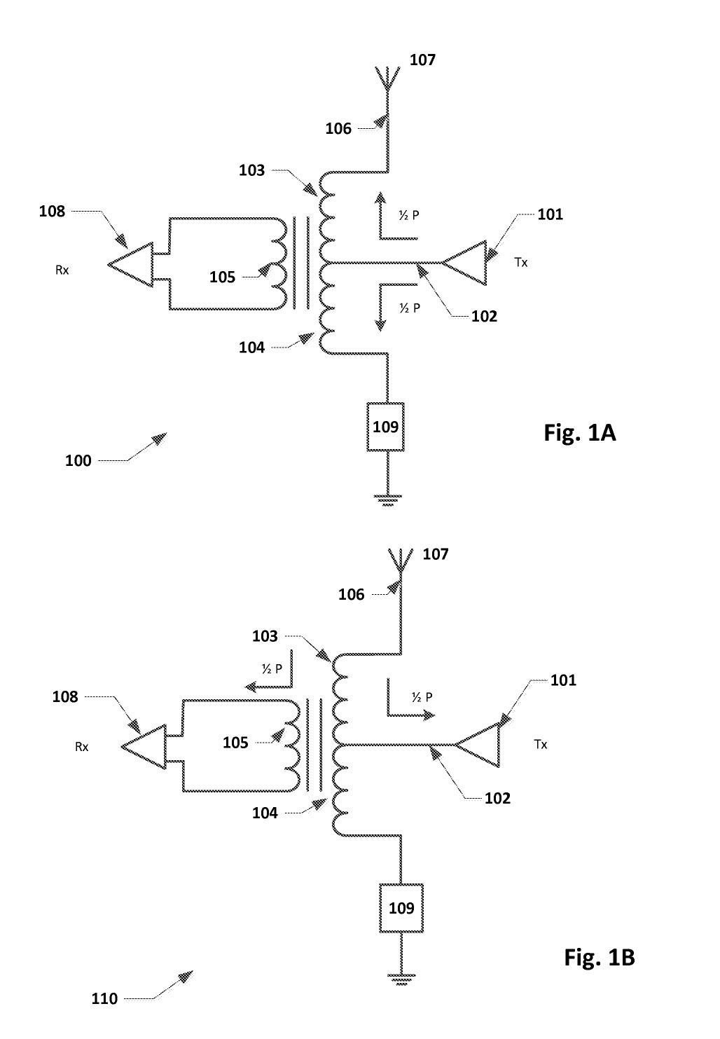

Prior arts FIGS. 1A-1B depict a center tapped hybrid transformer based duplexer. FIG. 1A illustrates a center tapped hybrid transformer based duplexer system 100 showing a transmit signal flow. The system 100 comprises a power amplifier 101 which is connected to a power amplifier port 102, a first winding 103, a second winding 104, a third winding 105, an antenna 107 connected to an antenna port 106, a differential amplifier 108 and a load 109. A center tapped hybrid transformer has three windings which is configured as a circuit having four branches. If a signal arrives at one branch, the signal is divided between the adjacent branches but does not appear at the opposite branch. Therefore, during transmission, the power amplifier 101 delivers the signal to be transmitted to the first winding 103 and the second winding 104 through the power amplifier port 102. One half of the signal is transmitted through the antenna 107 and the other half of the signal goes to the load 109. Only half of the desired signal power is being transmitted. Therefore, there is the inherent 3 dB insertion loss, as half of the desired signal power is delivered to the undesired port which is the load. Due to opposite phases of the transmit signal appearing in the first winding 103 and the second winding 104, the transmit signal does not appear in winding 105, hence isolating the transmit signal from the receiver input.

FIG. 1B illustrates a center tapped hybrid transformer based duplexer system 110 showing the receive signal flow. The antenna 107 receives the signal. While one half of the received signal power is delivered to the differential amplifier 108, the other half of the received signal power is delivered to the undesired port which is the power amplifier port 102. Therefore, there is the inherent 3 dB insertion loss. The power delivered to the desired port can be changed by adjusting the turns ratio of the transformer. However, if the insertion loss experienced by the transmit signal is improved, the insertion loss experienced by the receive signal is degraded and vice versa.

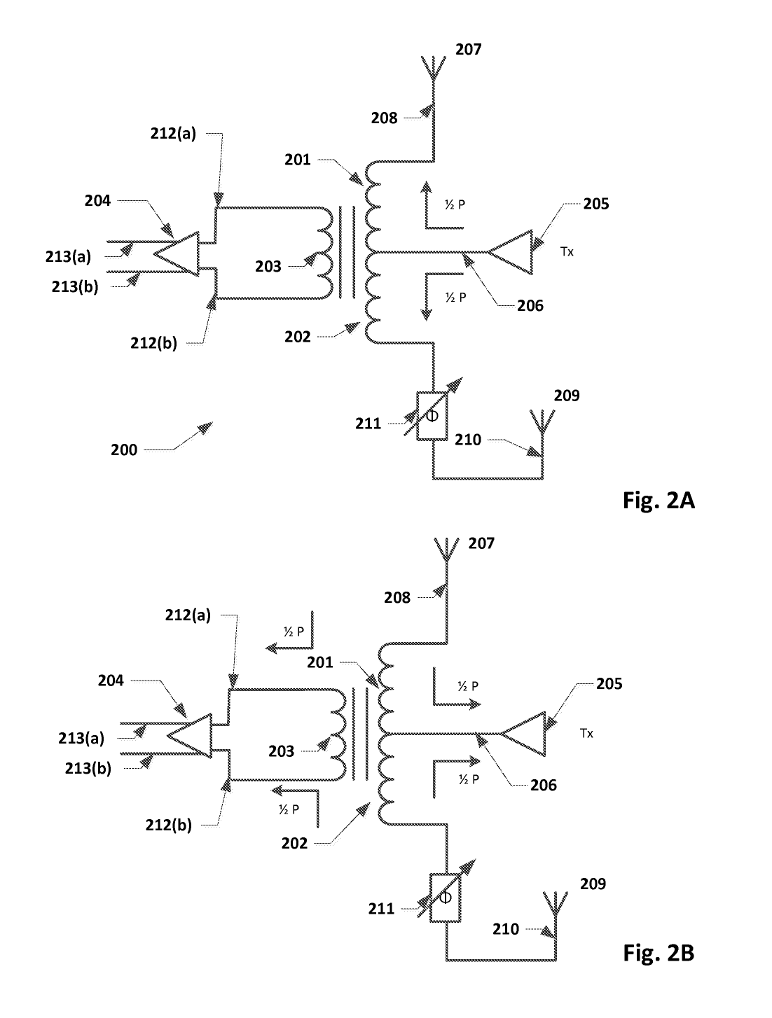

The present disclosure discloses circuitry and a method to minimize the insertion loss in a transformer based duplexer system. A Hybrid Transformer based Duplexer (HTBD) is disclosed. FIG. 2A illustrates an embodiment of HTBD showing transmit signal flow. The HTBD 200 comprises a first winding 201, a second winding 202, a third winding 203, a differential low noise amplifier 204, a power amplifier 205 connected to a power amplifier port 206, a first antenna 207 connected to a first antenna port 208, a second antenna 209 connected to a second antenna port 210 and a phase shifter circuit 211. The first winding 201 is coupled between the power amplifier port 206 and the first antenna port 208. The second winding 202 is coupled between the power amplifier port 206 and the second antenna port 210. The differential low noise amplifier (DLNA) 204 comprises a first input 212(a), a second input 212(b), a first output 213(a) and a second output 213(b). The third winding 203 is coupled between the first input 212(a) and the second input 212(b) of the differential low noise amplifier 204. A first coupling is formed between the first winding 201 and the third winding 203. A second coupling is formed between the second winding 202 and the third winding 203. The power amplifier port 206 is coupled to the power amplifier 205 and comprises a transmit signal. The first antenna port 208 is configured to transmit the transmit signal from the power amplifier port 206 through the antenna 207. The second antenna port 210 is configured to transmit the transmit signal from the power amplifier port 206 through the antenna 209. The power of the transmit signal from the power amplifier port is split in half between the first antenna port 208 and the second antenna port 210. However, both these signals, the signal at the first antenna port 208 and the signal at the second antenna port 210, are transmitted. Hence, the insertion loss during transmission is improved, as the entire power is transmitted through the two antenna ports 208 and 210. No transmit signal power is delivered to an undesired port.

The DLNA 204 is in the receive signal flow path of the HTBD and hence in some embodiments, it can be referred as a receiving amplifier. The power amplifier is in the transmit signal flow path of the HTBD and hence in some embodiments, it can be referred as a transmitting amplifier port.

FIG. 2B illustrates an embodiment of HTBD showing the receive signal flow. The first antenna port 208 is configured to receive a first signal via the antenna 207. The second antenna port 210 is configured to receive a second signal via the antenna 209. One half of the signal received at the first antenna port 208 is delivered to the first input 212(a) of the DLNA 204 and the other half of the signal is delivered to the undesired port which is the power amplifier port 206. Similarly, one half of the signal received at the second antenna port 210 is delivered to the second input 212(b) of the DLNA 204 and the other half of the signal is delivered to the power amplifier port 206. Even though, half of each signal received at the two antenna ports (208 and 210) is delivered to the undesired port, because the two received signals are out-of-phase they cancel at 206, and the signals arriving at the DLNA 204 are constructively summed to make up for the loss at the undesired port. The phase shifter circuit 211 is coupled between the second winding 202 and the second antenna port 210. The phase shifter circuit 211 is configured to shift the phase of the second signal received at the second antenna port 210. The phase shifter circuit 211 shifts the phase of the second signal in such a way that the first signal received and the second signal received are constructively summed at the DLNA 204. A differential amplifier amplifies a signal which is the difference between its two input signals. Therefore, if the two inputs of the differential amplifier are in-phase, they are destructively summed at the output of the differential amplifier. For example, if the first signal and the second signal received at the first antenna port 208 and the second antenna port 210 respectively have the same phase, then the phase shifter circuit 211 is configured to shift the phase of the signal by 180 degrees.

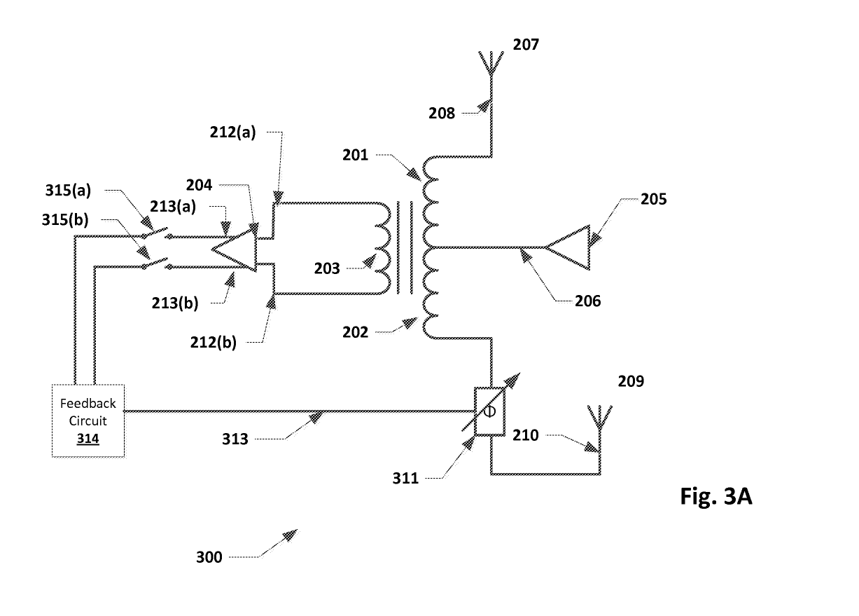

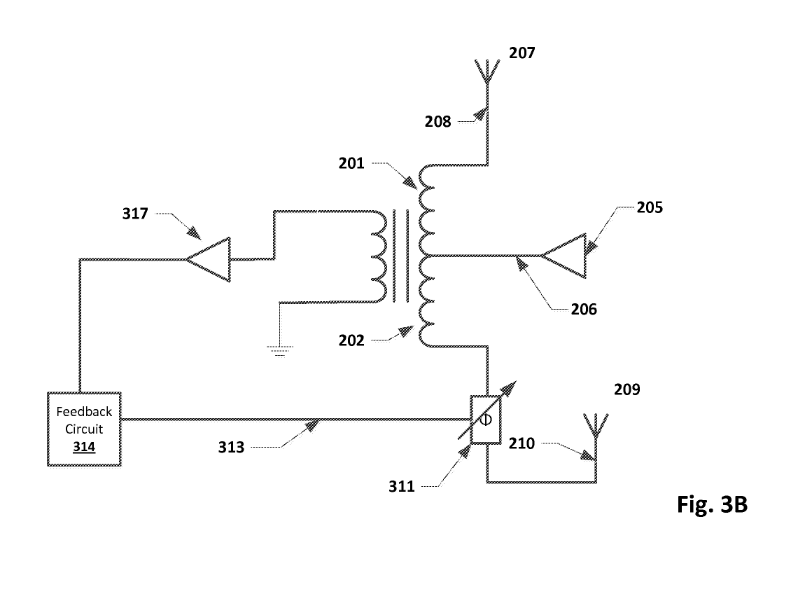

In another embodiment, a DLNA 204 is replaced by a single ended low noise amplifier. The working of the HTBD comprising the amplifier circuit is appreciated in FIG. 3B.

In RF communication, due to multiple path propagation and other environmental factors, the signals received at the first antenna port 208 and the second antenna port 210 may not exactly have the same phase. In such cases, it is advantageous to configure the phase shifter circuit 211 such that the second signal received at the second antenna port 210 is exactly 180 degrees out of phase with respect to the first signal received at the first antenna port 208. Having a programmable phase shifter enables the HTBD to operate at a multitude of frequencies, because the received signals arrive at the two antennas at phases which vary with frequency. FIG. 3A illustrates an embodiment of HTBD with a programmable phase shifter circuit.

The HTBD system 300 of FIG. 3A comprises the components present in FIG. 2. In addition to these components, the HTBD system 300 comprises a feedback circuit 314 coupled between the first output 213(a) and the second output 213(b) of the DLNA 204. The feedback circuit is configured to generate a feedback information 313 based on the first signal and the second signal received at the first antenna port 208 and the second antenna port 210, respectively. Further, the phase shifter circuit 211 of FIG. 2 is replaced with a programmable phase shifter circuit 311 in FIG. 3A. The programmable phase shifter circuit 311 is configured to shift the phase of the second signal based on the feedback information 313 generated by the feedback circuit 314. The feedback information generated by the feedback circuit 314, in some cases, is the phase difference between the first signal and the second signal received.

In some embodiments, the feedback circuit 314 is coupled to the baseband components, as it may be easier and more efficient to calculate the phase difference between the first signal and the second signal in baseband. One way of generating the feedback information 313 is by independently measuring the phase of each received signal (the first signal and the second signal) and calculating the phase difference between the two received signals. For example, one of the signal paths of the DLNA 204 can be biased in the off-state, and the phase of the received signal in the signal path biased in the on-state can be calculated. This is achieved by the switches 315(a) and 315(b) at the first output 213(a) and the second output 213(b) of the DLNA 204. While in FIG. 3A the switches are explicitly shown, in a different embodiment the switch function can be implemented in the output stage of the low noise amplifier such as a cascode amplifier.

The programmable phase shifter circuit 311, in one embodiment, is calibrated initially to shift the phase of the second signal based on the feedback information 313 received from the feedback circuit 314. In another embodiment, the programmable phase shifter circuit 311 is calibrated periodically. In another embodiment, the feedback circuit 314 is configured to continuously generate feedback information 313 based on the first signal and the second signal received at the first antenna port 208 and the second antenna port 210. The programmable phase shifter circuit 311 is configured to adaptively change the phase of the second signal based on the feedback information 313 received from the feedback circuit 314.

FIG. 3B illustrates an embodiment of the HTBD system comprising a single ended low noise amplifier. The HTBD system of FIG. 3B comprises a structure similar to the HTBD system of FIG. 3A; however, the DLNA 204 of FIG. 3A is replaced with a single ended low noise amplifier 317. This embodiment does not require a switch or switching function at its output. In this case instead of computing the phase difference between the two received signals, the maximum needs to be determined for the output signal from the single ended low noise amplifier 317.

In RF communication, it is important to filter out the out of band blockers. The out of band blockers cause a degradation of the desired signal. If the out of band blockers have a high power when compared to the in-band signal (desired signal), the desired signal may be buried under the high powered out of band blockers which may result in amplifier saturation and tougher decoding of the desired signal. Therefore, it is advantageous to filter out the out of band blockers.

The present disclosure discloses a Tunable Transformer Based Duplexer (TTBD) to provide isolation between the transmit signal and the receive signal and also to provide out of band rejection of the receive blockers.

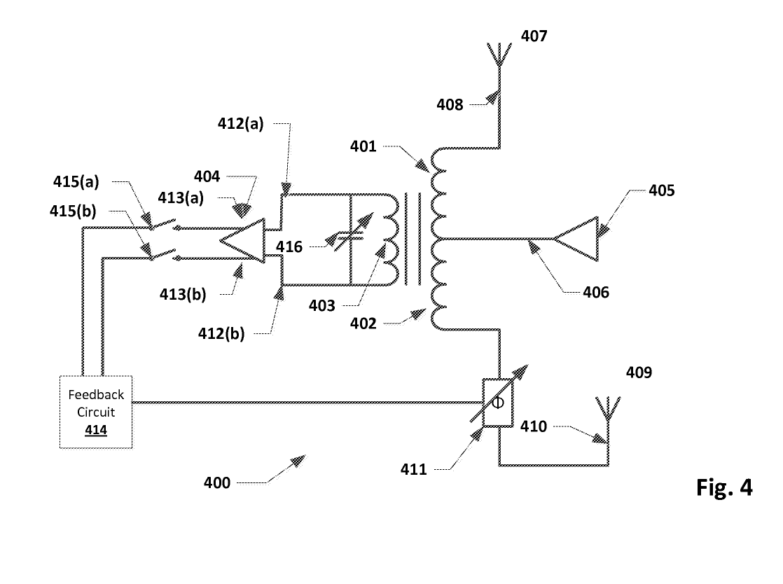

FIG. 4 illustrates a TTBD system. The TTBD 400 comprises a first winding 401, a second winding 402, a third winding 403, a differential low noise amplifier 404, a power amplifier 405 connected to a power amplifier port 406, a first antenna 407 connected to a first antenna port 408, a second antenna 409 connected to a second antenna port 410, a tunable capacitance 416 and a phase shifter circuit 411. The first winding 401 is coupled between the power amplifier port 406 and the first antenna port 408. The second winding 402 is coupled between the power amplifier port 406 and the second antenna port 410. The differential low noise amplifier (DLNA) 404 comprises a first input 412(a), a second input 412(b), a first output 413(a) and a second output 413(b). The third winding 403 is coupled between the first input 412(a) and the second input 412(b) of the differential low noise amplifier 404. A first coupling is formed between the first winding 401 and the third winding 403. A second coupling is formed between the second winding 402 and the third winding 403. The power amplifier port 406 is coupled to the power amplifier 405 and comprises a transmit signal. The tunable capacitance 416 is coupled between the first terminal and the second terminal of the third winding 403.

During transmission, the first antenna port 408 is configured to transmit the transmit signal from the power amplifier port 406 through the antenna 407. The second antenna port 410 is configured to transmit the transmit signal from the power amplifier port 406 through the antenna 409. During reception, the first antenna port 408 is configured to receive a first signal via the antenna 407. The second antenna port 410 is configured to receive a second signal via the antenna 409.

The phase shifter circuit 411 is coupled between the second winding 402 and the second antenna port 410. The phase shifter circuit 411 is configured to shift the phase of the second signal received at the second antenna port 410. The phase shifter circuit 411 shifts the phase of the second signal in such a way that the first signal received and the second signal received are summed at the DLNA 404.

The third winding 403 has an inductance. The tunable capacitor 416 can be tuned to a desired value such that a tunable band-pass filtering (LC filter) is formed to filter out the out of band blockers. Thus, the TTBD system provides a very low insertion loss as well as broadband replacement of the expensive acoustic filter based duplexers.

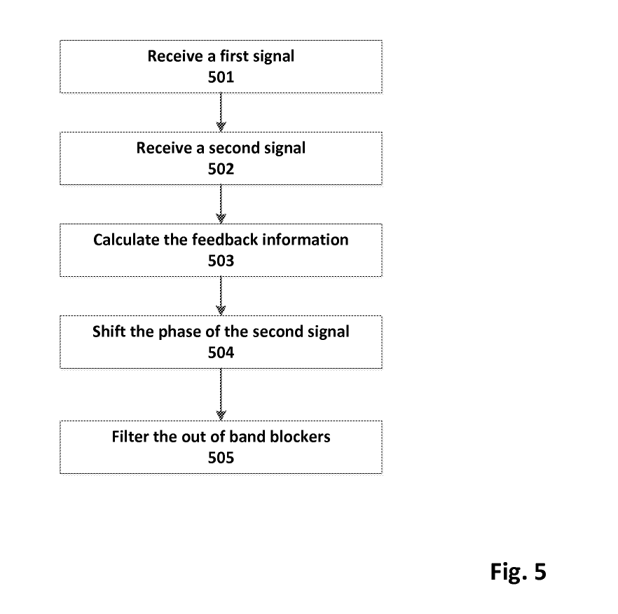

FIG. 5 illustrates a method to optimize the transmit insertion loss and the receive insertion loss and to filter the out of band blockers in a transformer based duplexer system. The structure to this method is similar to the structure appreciated in FIG. 3. The act 501 comprises receiving a first signal at a first antenna port. The act 502 comprises receiving a second signal at a second antenna port. The act 503 comprises calculating the feedback information based on the first signal received in the act 501 and the second signal received in the act 502. The feedback information is generated by a feedback circuit. The act 504 comprises the shifting of the phase of the second signal received in act 502, using a phase shifter, based on the generated feedback information. The act 505 comprises the filtering the out of band blockers by using a capacitance in the transformer based duplexer system.

Although the disclosure has been illustrated and described with respect to one or more implementations, alterations and/or modifications may be made to the illustrated examples without departing from the spirit and scope of the appended claims.

One or more of the operations described can constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering will be appreciated by one skilled in the art having the benefit of this description. Further, it will be understood that not all operations are necessarily present in each embodiment provided herein.

Moreover, in particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations. In addition, while a particular feature may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

Examples can include subject matter such as a method, means for performing acts or blocks of the method, at least one machine-readable medium including instructions that, when performed by a machine cause the machine to perform acts of the method or of an apparatus or system for concurrent communication using multiple communication technologies according to embodiments and examples described herein.

Example 1 is a hybrid transformer based duplexer system, comprising: a transmitting amplifier port; a receiving amplifier; a first antenna port and a second antenna port; a first winding coupled between the transmitting amplifier port and the first antenna port; a second winding coupled between the transmitting amplifier port and the second antenna port; a third winding that couples the receiving amplifier to both the first winding and the second winding; and a programmable phase shifter coupled between the second winding and the second antenna port.

Example 2 is a hybrid transformer duplexer system including the subject matter of example 1, including or omitting elements, wherein the first winding is configured to convey a first transmit signal from the transmitting amplifier port to the first antenna port and to convey a first receive signal from the first antenna port to the third winding.

Example 3 is a hybrid transformer duplexer system including the subject matter of examples 1-2, including or omitting elements, wherein the second winding is configured to convey a second transmit signal from the transmitting amplifier port to the second antenna port and to convey a second receive signal from the second antenna port to the third winding.

Example 4 is a hybrid transformer duplexer system including the subject matter of examples 1-3, including or omitting elements, wherein the third winding is configured to convey the first receive signal, which have been received by the first antenna and have been conveyed through the first winding, to the receiving amplifier and wherein the third winding is configured to convey the second receive signal, which have been received by the second antenna and have been conveyed through the second winding, to the receiving amplifier.

Example 5 is a hybrid transformer duplexer system including the subject matter of examples 1-4, including or omitting elements, wherein the programmable phase shifter is configured to shift the phase of the second receive signal such that the first receive signal and the second receive signal constructively interfere at an input of the receiving amplifier.

Example 6 is a hybrid transformer duplexer system including the subject matter of examples 1-5, including or omitting elements, further comprising: a feedback circuit coupled between an output of the receiving amplifier and an input of the programmable phase shifter.

Example 7 is a hybrid transformer duplexer system including the subject matter of examples 1-6, including or omitting elements, wherein the programmable phase shifter is configured to shift the phase of the second receive signal based on feedback information obtained from the feedback circuit.

Example 8 is a hybrid transformer duplexer system including the subject matter of examples 1-7, including or omitting elements, wherein the receiving amplifier comprises a differential amplifier comprising a first input, a second input, a first output and a second output.

Example 8 is a hybrid transformer duplexer system including the subject matter of examples 1-7, including or omitting elements, wherein the receiving amplifier comprises a differential amplifier comprising a first input, a second input, a first output and a second output.

Example 9 is a hybrid transformer duplexer system including the subject matter of examples 1-8, including or omitting elements, wherein the receiving amplifier comprises a single ended amplifier comprising a first input and a first output.

Example 10 is a tunable transformer based duplexer system, comprising: a first antenna port and a second antenna port; a first winding coupled between a transmitting port and the first antenna port, wherein the first antenna port is configured to receive a first signal; a second winding coupled between the transmitting port and the second antenna port, wherein the second antenna port is configured to receive a second signal; a receiving amplifier comprising at least one input and at least one output; a third winding comprising a first terminal and a second terminal, wherein the third winding is coupled to the at least one input of the receiving amplifier; wherein a first coupling is formed between the first winding and the third winding; wherein a second coupling is formed between the second winding and the third winding; a tunable capacitor coupled between the first terminal and the second terminal of the third winding; and a programmable phase shifter coupled between the second winding and the second antenna port, wherein the programmable phase shifter is configured to shift a phase of the second signal.

Example 11 is a tunable transformer duplexer system including the subject matter of example 10, including or omitting elements, wherein the third winding and the tunable capacitor together form a band-pass filter.

Example 12 is a tunable transformer duplexer system including the subject matter of examples 10-11, including or omitting elements, further comprising: a transmitting amplifier comprising an output coupled to the transmitting port and an input configured to receive a transmit signal.

Example 13 is a tunable transformer duplexer system including the subject matter of examples 10-12, including or omitting elements, wherein the first antenna port is further configured to convey signals from the transmitting amplifier to the first antenna port; and wherein the second antenna port is further configured to convey signals from the transmitting amplifier to the first antenna port.

Example 14 is a tunable transformer duplexer system including the subject matter of examples 10-13, including or omitting elements, wherein the programmable phase shifter is configured to shift the phase of the second signal to generate a phase shifted second signal, such that the phase shifted second signal is 180 degrees out of phase with the first signal.

Example 15 is a tunable transformer duplexer system including the subject matter of examples 10-14, including or omitting elements, wherein the programmable phase shifter is configured to shift the phase of the second signal to generate a phase shifted second signal, such that the first signal at the first terminal of the third winding is 180 degrees out of phase with the second signal at the second terminal of the third winding.

Example 16 is a tunable transformer duplexer system including the subject matter of examples 10-15, including or omitting elements, further comprising: a feedback circuit coupled to the at least one output of the receiving amplifier, wherein the feedback circuit is configured to generate a feedback information based on the first signal and the second signal.

Example 17 is a tunable transformer duplexer system including the subject matter of examples 10-16, including or omitting elements, wherein the programmable phase shifter is configured to shift the phase of the second signal based on the feedback information obtained from the feedback circuit.

Example 18 is a tunable transformer duplexer system including the subject matter of examples 10-17, including or omitting elements, wherein the receiving amplifier comprises a differential amplifier comprising a first input, a second input, a first output and a second output.

Example 19 is a tunable transformer duplexer system including the subject matter of examples 10-18, including or omitting elements, wherein the receiving amplifier comprises a single ended amplifier comprising a first input and a first output.

Example 20 is a method of operating a transformer based duplexer system comprising a first winding coupled between a transmitting port and a first antenna port, a second winding coupled between the transmitting port and a second antenna port, a receiving amplifier comprising at least one input and at least one output, and a third winding coupled between the input of the receiving amplifier and both the first winding and the second winding, the method comprising: receiving, by the first antenna port, a first signal; receiving, by the second antenna port, a second signal; shifting, by a programmable phase shifter, a phase of the second signal to generate a phase shifted second signal; coupling the first signal between the first winding and the third winding; and coupling the phase shifted second signal between the second winding and the third winding.

Example 21 is a method including the subject matter of example 20, including or omitting elements, further comprising: generating, by a feedback circuit, feedback information based on the first signal and the second signal; and filtering, by a capacitance and the third winding to which it is coupled, out of band blockers.

Example 22 is a method including the subject matter of example 20-21, including or omitting elements, wherein the shifting the phase of the signal, by a programmable phase shifter circuit, is based on the generated feedback information.

Example 23 is a method including the subject matter of example 20-22, including or omitting elements, wherein the phase shifted second signal is 180 degrees out of phase with the first signal.

Example 24 is a hybrid transformer duplexer system to optimize a transmit insertion loss and a receive insertion loss, the hybrid transformer based duplexer system comprising: a first winding coupled between a power amplifier port and a first antenna port, wherein the first antenna port is configured to receive a first signal; a second winding coupled between the power amplifier port and a second antenna port, wherein the second antenna port is configured to receive a second signal; an amplifier circuit comprising at least one input and at least one output; a third winding coupled to the at least one input of the amplifier circuit, wherein a first coupling is formed between the first winding and the third winding, and wherein a second coupling is formed between the second winding and the third winding; and a programmable phase shifter circuit coupled between the second winding and the second antenna port, wherein the programmable phase shifter circuit is configured to shift a phase of the second signal.

Example 25 is a hybrid transformer duplexer system including the subject matter of example 24, including or omitting elements, further comprising: a power amplifier comprising an output coupled to the power amplifier port and an input coupled to a transmit port and configured to receive a transmit signal.

Example 26 is a hybrid transformer duplexer system including the subject matter of examples 24-25, including or omitting elements, wherein the first antenna port is further configured to transmit the transmit signal from the power amplifier port; and wherein the second antenna port is further configured to transmit the transmit signal from the power amplifier port.

Example 27 is a hybrid transformer duplexer system including the subject matter of examples 24-26, including or omitting elements, wherein the programmable phase shifter circuit is configured to shift the phase of the second signal to generate a phase shifted second signal, such that the phase shifted second signal is 180 degrees out of phase with the first signal.

Example 28 is a hybrid transformer duplexer system including the subject matter of examples 24-27, including or omitting elements, further comprising a feedback circuit coupled to the at least one output of the amplifier circuit, wherein the feedback circuit is configured to generate a feedback information based on the first signal and the second signal.

Example 29 is a hybrid transformer duplexer system including the subject matter of examples 24-28, including or omitting elements, wherein the programmable phase shifter circuit is configured to shift the phase of the second signal based on the feedback information obtained from the feedback circuit.

Example 30 is a hybrid transformer duplexer system including the subject matter of examples 24-29, including or omitting elements, wherein the feedback information generated by the feedback circuit is based on a determined phase difference between the first signal and the second signal.

Example 31 is a hybrid transformer duplexer system including the subject matter of examples 24-30, including or omitting elements, wherein the amplifier circuit comprises a differential amplifier comprising a first input, a second input, a first output and a second output.

Example 32 is a hybrid transformer duplexer system including the subject matter of examples 24-31, including or omitting elements, wherein the amplifier circuit comprises a single ended amplifier comprising a first input and a first output.

1. A hybrid transformer based duplexer system, comprising:
a transmitting amplifier port;
a receiving amplifier;
a first antenna port and a second antenna port;
a first winding coupled between the transmitting amplifier port and the first antenna port;
a second winding coupled between the transmitting amplifier port and the second antenna port;
a third winding having a first terminal and a second terminal at ends thereof that couples the receiving amplifier to both the first winding and the second winding;
a tunable capacitor coupled between the first terminal and the second terminal of the third winding, thereby being in parallel with the third winding; and
a programmable phase shifter coupled between the second winding and the second antenna port.

2. The hybrid transformer based duplexer system of claim 1, wherein the first winding is configured to convey a first transmit signal from the transmitting amplifier port to the first antenna port and to convey a first receive signal from the first antenna port to the third winding.

3. The hybrid transformer based duplexer system of claim 2, wherein the second winding is configured to convey a second transmit signal from the transmitting amplifier port to the second antenna port and to convey a second receive signal from the second antenna port to the third winding.

4. The hybrid transformer based duplexer system of claim 3, wherein the third winding is configured to convey the first receive signal, which have been received by the first antenna and have been conveyed through the first winding, to the receiving amplifier and wherein the third winding is configured to convey the second receive signal, which have been received by the second antenna and have been conveyed through the second winding, to the receiving amplifier.

5. The hybrid transformer based duplexer system of claim 4, wherein the programmable phase shifter is configured to shift the phase of the second receive signal such that the first receive signal and the second receive signal constructively interfere at an input of the receiving amplifier.

6. The hybrid transformer based duplexer system of claim 5, further comprising:
a feedback circuit coupled between an output of the receiving amplifier and an input of the programmable phase shifter.

7. The hybrid transformer based duplexer system of claim 6,
wherein the programmable phase shifter is configured to shift the phase of the second receive signal based on feedback information obtained from the feedback circuit.

8. The hybrid transformer based duplexer system of claim 1,
wherein the receiving amplifier comprises a differential amplifier comprising a first input, a second input, a first output and a second output.

9. The hybrid transformer based duplexer system of claim 1,
wherein the receiving amplifier comprises a single ended amplifier comprising a first input and a first output.

10. A tunable transformer based duplexer system, comprising:
a first antenna port and a second antenna port;
a first winding coupled between a transmitting port and the first antenna port, wherein the first antenna port is configured to receive a first signal;
a second winding coupled between the transmitting port and the second antenna port, wherein the second antenna port is configured to receive a second signal;
a receiving amplifier comprising at least one input and at least one output;
a third winding comprising a first terminal and a second terminal,
wherein the third winding is coupled to the at least one input of the receiving amplifier;
wherein a first coupling is formed between the first winding and the third winding;
wherein a second coupling is formed between the second winding and the third winding;
a tunable capacitor coupled between the first terminal and the second terminal of the third winding; and
a programmable phase shifter coupled between the second winding and the second antenna port, wherein the programmable phase shifter is configured to shift a phase of the second signal.

11. The tunable transformer based duplexer system of claim 10,
wherein the third winding and the tunable capacitor together form a band-pass filter.

12. The tunable transformer based duplexer system of claim 10, further comprising:
a transmitting amplifier comprising an output coupled to the transmitting port and an input configured to receive a transmit signal.

13. The tunable transformer based duplexer system of claim 12,
wherein the first antenna port is further configured to convey signals from the transmitting amplifier to the first antenna port; and
wherein the second antenna port is further configured to convey signals from the transmitting amplifier to the first antenna port.

14. The tunable transformer based duplexer system of claim 10,
wherein the programmable phase shifter is configured to shift the phase of the second signal to generate a phase shifted second signal, such that the phase shifted second signal is 180 degrees out of phase with the first signal.

15. The tunable transformer based duplexer system of claim 10,
wherein the programmable phase shifter is configured to shift the phase of the second signal to generate a phase shifted second signal, such that the first signal at the first terminal of the third winding is 180 degrees out of phase with the second signal at the second terminal of the third winding.

16. The tunable transformer based duplexer system of claim 15, further comprising:
a feedback circuit coupled to the at least one output of the receiving amplifier, wherein the feedback circuit is configured to generate a feedback information based on the first signal and the second signal.

17. The tunable transformer based duplexer system of claim 16,
wherein the programmable phase shifter is configured to shift the phase of the second signal based on the feedback information obtained from the feedback circuit.

18. The tunable transformer based duplexer system of claim 10,
wherein the receiving amplifier comprises a differential amplifier comprising a first input, a second input, a first output and a second output.

19. The tunable transformer based duplexer system of claim 10,
wherein the receiving amplifier comprises a single ended amplifier comprising a first input and a first output.

20. A method of operating a transformer based duplexer system comprising a first winding coupled between a transmitting port and a first antenna port, a second winding coupled between the transmitting port and a second antenna port, a receiving amplifier comprising at least one input and at least one output, and a third winding coupled between the input of the receiving amplifier and both the first winding and the second winding, the method comprising:
receiving, by the first antenna port, a first signal;
receiving, by the second antenna port, a second signal;
shifting, by a programmable phase shifter, a phase of the second signal to generate a phase shifted second signal;
coupling a tunable capacitor in parallel with the third winding;
coupling the first signal between the first winding and the third winding; and
coupling the phase shifted second signal between the second winding and the third winding.

21. The method of claim 20, further comprising:
generating, by a feedback circuit, feedback information based on the first signal and the second signal; and
filtering, by the tunable capacitor and the third winding to which it is coupled, out of band blockers.

22. The method of claim 21,
wherein the shifting the phase of the signal, by a programmable phase shifter circuit, is based on the generated feedback information.

23. The method of claim 22,
wherein the phase shifted second signal is 180 degrees out of phase with the first signal.
